(19) United States
(12) Patent Application Publication
(10) Pub. No.: US 2023/0080636 A1
(43) Pub. Date: Mar. 16, 2023

(54) DEVICE STRUCTURE FOR POWER SEMICONDUCTOR TRANSISTOR

(71) Applicant: GaN Systems Inc., Kanata (CA)

(72) Inventor: Thomas MACELWEE, Nepean (CA)

(21) Appl. No.: 17/881,096

(22) Filed: Aug. 4, 2022

Related U.S. Application Data
(60) Provisional application No. 63/244,463, filed on Sep. 15, 2021.

(51) Int. Cl. H01L 29/40; H01L 29/778; H01L 29/20; H01L 29/417

(52) U.S. Cl. CPC H01L 29/404; H01L 29/7786; H01L 29/2003; H01L 29/41775; H01L 29/41758

(57) ABSTRACT

A semiconductor device structure for a power transistor structure wherein a drain terminal structure comprises field plates to control and reduce the peak intensity of the channel electric field at the drain terminal. By forming multiple field plates with the existing metallization layers, the generation of hot carriers and impact ionization near the drain can be reduced. For example, in a GaN HEMT, this effect is achieved with two field plates that have different capacitive coupling and overlap with the drain ohmic contact to achieve a reduction in the channel electric field. The use of this drain terminal structure may offer a reduction in increase of R_{dson} with aging that may be observed in devices after high voltage stress.

### CROSS-REFERENCE TO RELATED APPLICATION(S)

This application claims priority from U.S. provisional patent application No. 63/244,463, filed Sep. 15, 2021, entitled “DEVICE STRUCTURE FOR POWER SEMICONDUCTOR TRANSISTOR”, which is incorporated herein by reference in its entirety.

### TECHNICAL FIELD

This invention relates to device structures for semiconductor power transistors, and more particularly relates to Gallium Nitride (GaN) semiconductor power transistors, such as GaN HEMTs.

### BACKGROUND

GaN power transistors for high voltage applications, e.g. 100V to 650V applications, are subject to high voltage stress in the channel region near the drain terminal. As a result, hot carriers in the channel region near the drain terminal, which are subject to high electric fields, may be created and lead to formation of traps. The latter adversely affect device performance and reliability, e.g. leading to an increase in R_{dson} (drain-source on-resistance) with aging.

Thus, there is a need for solutions to address this problem, e.g. to provide GaN power transistors device structures which reduce high voltage stress in the region of the drain terminal.

### SUMMARY OF INVENTION

The present invention seeks to provide a GaN power transistor structure that reduces high voltage stress in the channel region near the drain terminal.

One aspect of the invention provides a semiconductor device structure for a power transistor comprising a drain ohmic contact and a drain terminal structure, wherein the drain terminal structure comprises a plurality of drain field plates that have different capacitive coupling and overlap with the drain ohmic contact to achieve a reduction in a peak intensity of a channel electric field near the drain terminal.

For example, the power transistor is a GaN semiconductor power transistor, e.g. an e-mode GaN HEMT, comprising a plurality of metallization layers and intermetal dielectric layer defining source, drain and gate contact structures, wherein the drain contact structure comprises a drain ohmic contact and a drain terminal structure, the drain terminal structure comprising a plurality of drain field plates that have different capacitive coupling and overlap with the drain ohmic contact to achieve the reduction in a peak intensity of a channel electric field near the drain terminal.

In an embodiment, the plurality of drain field plates comprise first and second field plates formed by first and second metallization layers of said plurality of metallization layers, the first field plate having a first capacitive coupling and first overlap with the drain ohmic contact, and the second field plate having a second capacitative coupling and second overlap with the drain ohmic contact.

For example, the first field plate extends laterally beyond the drain ohmic contact by a first distance (over the channel region in a source direction), and the second field plate extends laterally by a first distance (over the channel region in a source direction) beyond the first field plate, wherein the second distance is greater than the first distance. The first and second field plate dimensions and thicknesses of intermetal dielectric layers are selected to provide said first and second capacitative couplings.

Example embodiments of the invention make use of field plates to control and reduce the peak intensity of the channel electric field near the drain terminal. By forming multiple field plates with the existing layers of metallization, the generation of hot carriers and impact ionization near the drain can be reduced. For example, this effect is achieved with two field plates that have different capacitive coupling and overlap of the drain ohmic contact to achieve the reduction in the channel electric field.

The foregoing and features, aspects and advantages of the present invention will become more apparent from the following detailed description, taken in conjunction with the accompanying drawings, of some illustrative embodiments of the invention, which description is by way of example only.

### BRIEF DESCRIPTION OF THE DRAWINGS

FIG. 1 shows a schematic cross-sectional diagram of a semiconductor device structure comprising a GaN semiconductor power transistor of an example embodiment;

FIG. 2 shows an enlarged schematic cross-sectional diagram of part of the GaN power transistor shown in FIG. 1, to show details of the drain terminal structure;

FIG. 3 shows schematic cross-sectional diagrams of four example drain termination structures A, B, C and D

FIG. 4 shows a table listing parameters of the field plate structure for some example device simulations for the electric field in the drain region; and

FIG. 5 shows plots of electric field as a function of distance from the edge of the drain contact for the example device simulations.

The foregoing and other objects, features, aspects and advantages of the present invention will become more apparent from the following detailed description, taken in conjunction with the accompanying drawings, of some illustrative embodiments of the invention, which description is by way of example only.

### DETAILED DESCRIPTION

Disclosed herein is a semiconductor device structure comprising a power semiconductor transistor, such as a GaN semiconductor power transistor, e.g. a GaN HEMT for high voltage, high current applications. The drain contact structure comprises plurality of drain field plates to control and reduce the peak intensity of the channel electric field in the vicinity of the drain terminal. By forming multiple field plates with the existing metallization layers, the generation of hot carriers and impact ionization near the drain can be reduced. For example, in a device structure of an example embodiment, this effect is achieved with two field plates that have different capacitive coupling and overlap of the drain ohmic contact to achieve the reduction in the channel electric field.

The use of this drain contact structure could result in a reduction in the increase in static Rdson with aging that may be observed in devices after prolonged high voltage stress. The reliability of the device should increase as a result, and the data sheet max Rdson value would reduce, resulting in an increase of the device value to the end customer. Reduction of channel hot carriers will reduce trap formation in the GaN HEMT.

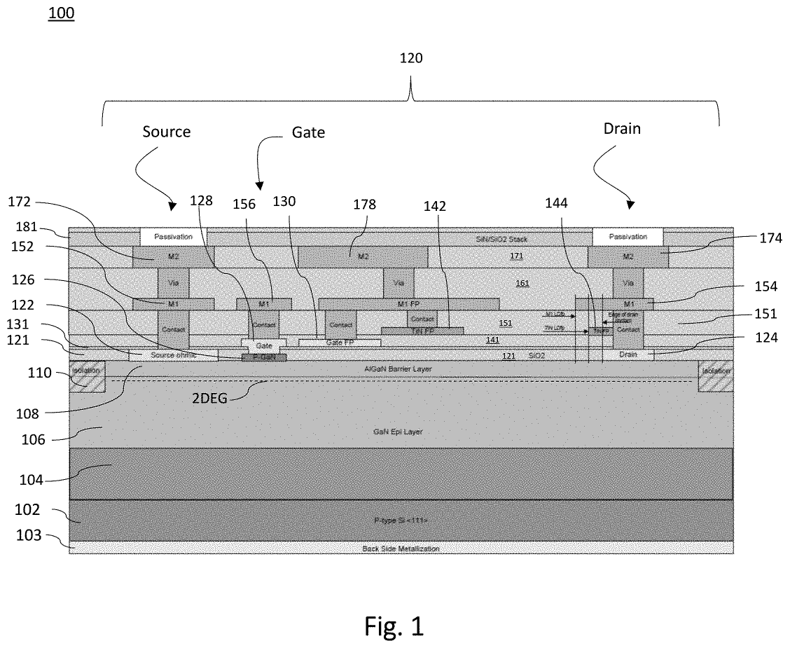

A schematic cross-sectional diagram of a semiconductor device structure 100 comprising a GaN power transistor is shown in FIG. 1. The device structure comprises a silicon substrate 102 on which is formed an epitaxial layer stack. The epitaxial layer stack comprises a plurality of layers 104 and a GaN/AlGaN heterostructure comprising a GaN epi-layer 106 and AlGaN barrier layer 108 which provides a 2DEG active region. There is an isolation region 110 separating the active region 120 of the transistor from surrounding areas. A first layer of dielectric 121 is formed on the active region and patterned to define openings for the source, drain and gate electrodes of the GaN transistor. A source electrode 122 is formed by a source ohmic contact layer and a drain electrode 124 is formed by a drain ohmic contact layer. The source ohmic contact layer and drain ohmic contact layer may be the same material. A gate electrode stack comprises layer of p-GaN 126 and a layer of gate metal 128. The gate metal layer also provides a gate field plate 130 which extends from the gate region towards the drain region. There is a passivation layer 131, e.g. silicon nitride, and another dielectric layer 141. A conductive metallization layer, e.g. TiN, is then provided on the dielectric layer 120 and patterned to define a gate field plate 142 and a drain field plate 144. Dielectric layer 151 is then provided and patterned to define contact openings for contacts to each of the source electrode, drain electrode, drain field plate 140, gate electrode, gate field plate 130 and gate field plate 142. The contact openings are filled with contact metal (labelled Contact). A first interconnect metallization layer M1 is patterned to define source metal 152, drain metal 154, gate metal 156 and gate field plate 158. Dielectric layer 161 is provided overall and patterned to define contact vias, which are filled with via metal (labelled Via) to form contacts to the source metal 152, drain metal 154, and gate field plate 158. Another dielectric layer 171, and a second interconnect metallization layer M2 are then provided and patterned to define a source contact 172, a drain contact 174, and a gate field plate contact 178. A passivation layer 181 comprises, e.g. a layer of silicon dioxide and a layer of silicon nitride.

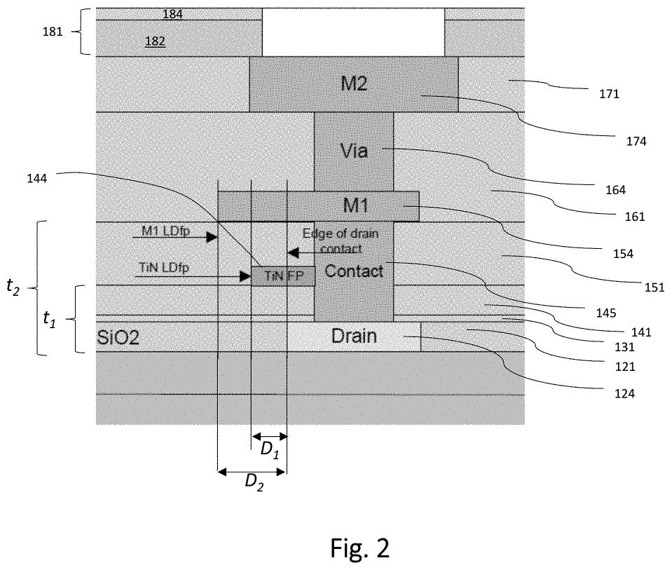

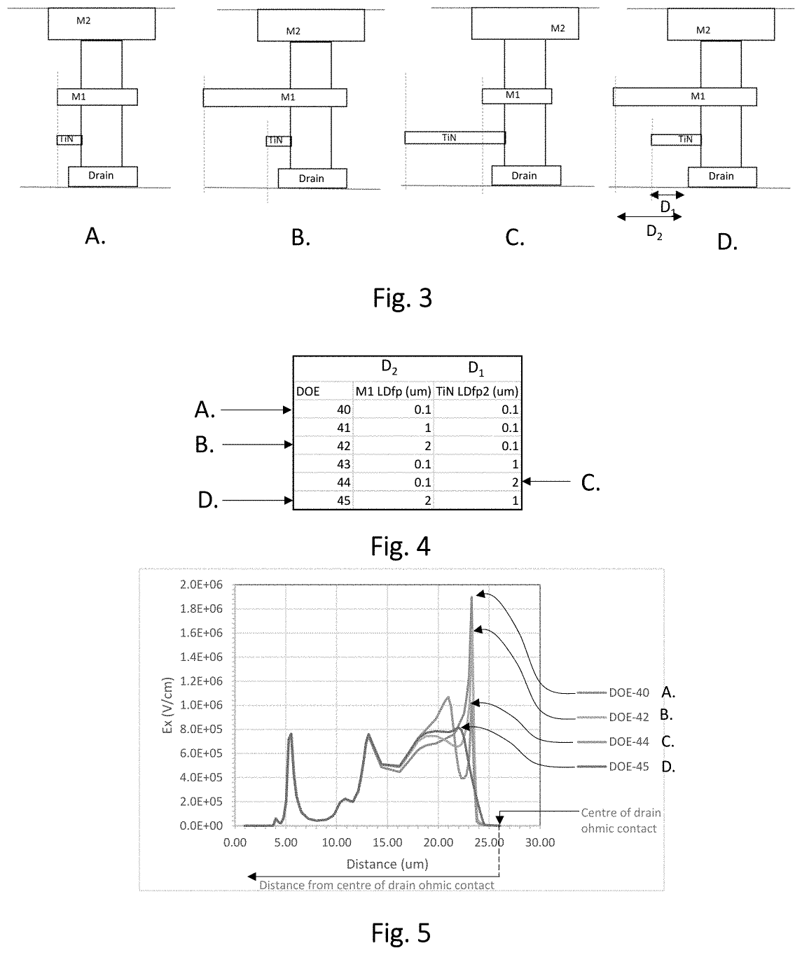

An enlarged cross-sectional view in the region of the drain contact structure of FIG. 1 is shown in FIG. 2. Layers and device structures are numbered as in FIG. 1. As illustrated, for this embodiment, the TiN drain field plate 144 extends laterally towards the gate/source region by a first distance D₁ from an edge of the drain contact 124, and the M1 drain field plate 154 extends laterally by a second distance D₂. The effect of varying the first and second distances D₁ LDfp2 (μm) and D₂ LDfp (μm) on the electric field as a function of distance from the edge of the drain contact 124 was investigated. Schematic cross-sectional diagrams of four example device structures comprising drain terminal structures having first and second drain field plates configured with different overlap and capacitative coupling are shown in FIG. 3, views A, B, C and D.

Some example dimensions for the example device structures illustrated schematically in FIG. 3 are shown in the table in FIG. 4. The graph in FIG. 5 shows plots of simulated electric field as a function of the lateral distance from the edge of the drain electrode (drain ohmic contact) in a direction towards the source (source direction).

As illustrated in the example plots of simulated electric field with distance shown in FIG. 5, changing the dimensions, e.g. overlap and capacitative coupling of the first and second drain field plates, significantly changes the peak electric field in the vicinity of the drain contact structure. For example, device structures C and D show a significantly reduced peak voltage in the channel region close to the drain terminal. Simulations predict that device structure D represents improved control of the electric field and approximates electrically an idealized slanted field plate design. Test structures are currently being evaluated to verify simulation results.

By forming multiple field plates with the existing metallization layers, the generation of hot carriers and impact ionization near the drain can be reduced. For example, in a GaN HEMT, this effect is achieved with two field plates that have different capacitive coupling and overlap with the drain ohmic contact to achieve a reduction in the channel electric field. For example, the first and second drain field plates are formed by conductive layers used to form other device structures, so that additional layers are not required, and minimal process changes are needed during fabrication. In the example embodiment, the first drain field plate 144 is formed by the same conductive layer, such as TiN, that is used to provide the gate field plate 142. The second drain field plate is defined by extending the first level interconnect metal (M1) defining the drain contact, to extend laterally from the drain contact structure over the channel region.

Although example embodiments of the invention have been described and illustrated in detail, it is to be clearly understood that the same is by way of illustration and example only and not to be taken by way of limitation, the scope of the present invention being limited only by the appended claims.

1. A semiconductor device structure for a lateral power transistor comprising a drain contact structure comprising a drain ohmic contact and a drain terminal structure, wherein the drain terminal structure comprises a plurality of drain field plates that have different capacitive coupling and overlap with the drain ohmic contact to achieve a reduction in a peak intensity of a channel electric field near the drain contact structure.

2. A semiconductor device structure comprising a lateral GaN semiconductor power transistor comprising a plurality of metallization layers and intermetal dielectric layers defining source, drain and gate contact structures, wherein the drain contact structure comprises a drain ohmic contact and a drain terminal structure, the drain terminal structure comprising a plurality of drain field plates that have different capacitive coupling and overlap with the drain ohmic contact to achieve a reduction in a peak intensity of a channel electric field near the drain contact structure.

3. The semiconductor device structure of claim 2, wherein the plurality of drain field plates comprises first and second drain field plates formed by first and second metallization layers of said plurality of metallization layers, the first drain field plate having a first capacitive coupling and first overlap with the drain ohmic contact, and the second drain field plate having a second capacitative coupling and second overlap with the drain ohmic contact.

4. The semiconductor device structure of claim 3, wherein the first drain field plate extends laterally beyond the drain ohmic contact by a first distance in a source direction, and the second drain field plate extends laterally beyond the first drain field plate by a second distance in the source direction, wherein the second distance is greater than the first distance.

5. The semiconductor device structure of claim 3, wherein the first drain field plate extends laterally beyond the drain ohmic contact by a first distance in a source direction, and the second drain field plate extends laterally beyond the first field plate by a second distance in the source direction, wherein the first distance is greater than the second distance.

6. The semiconductor device structure of claim 3, wherein dimensions of the first and second drain field plate and thicknesses of intermetal dielectric layers are selected to provide said first and second capacitative couplings.

7. The semiconductor device structure of claim 4, wherein the first distance is at least 1 μm.

8. The semiconductor device structure of claim 4, wherein the second distance is at least 1 μm.

9. The semiconductor device structure of claim 3 wherein the first metallization layer defining the first drain field plate is a metallization layer that also defines a gate field plate.

10. The semiconductor device structure of claim 9 wherein the first metallization layer is a layer of titanium nitride.

11. The semiconductor device structure of claim 2, wherein the lateral GaN semiconductor power transistor is an enhancement-mode GaN HEMT.
